(19) United States
(12) Patent Application Publication
(10) Pub. No.: US 2022/0235463 A1
(43) Pub. Date: Jul. 28, 2022

(54) SixNy AS A NUCLEATION LAYER FOR SiCxOy

(71) Applicant: Lam Research Corporation, Fremont, CA (US)

(72) Inventors: Guangbi Yuan, Beaverton, OR (US); Bo Gong, Sherwood, OR (US); Leva Narkeviciute, Menlo Park, CA (US); Bhadri Varadarajan, Beaverton, OR (US); Fengyuan Lai, Tualatin, OR (US); Andrew Mckerrow, Lake Oswego, OR (US)

(21) Appl. No.: 17/612,529

(22) PCT Filed: May 5, 2020
(86) PCT No.: PCT/US2020/031516

§ 371 Date: Nov. 18, 2021

Related U.S. Application Data
(60) Provisional application No. 62/850,343, filed on May 20, 2019.

(51) Int. Cl. C23C 16/455; C23C 16/02; C23C 16/50; C23C 16/46; C23C 16/34; C23C 16/32; H01L 21/02

(52) U.S. Cl. CPC C23C 16/45536; C23C 16/0272; C23C 16/50; C23C 16/466; C23C 16/345; C23C 16/325; H01L 21/0228; H01L 21/02167; H01L 21/0217; H01L 21/02126; H01L 21/022; H01L 21/02274; H01L 21/02304

(57) ABSTRACT

In one embodiment, the disclosed subject matter is a method to produce a substantially uniform, silicon-carbide layer over both dielectric materials and metal materials. In one example, the method includes forming a silicon-nitride layer over the dielectric materials and the metal materials, and forming the silicon carbide layer over the silicon-nitride layer. Other methods are disclosed.

### CLAIM OF PRIORITY

This application claims the priority benefit to U.S. Patent Application Ser. No. 62/850,343, filed on 20 May 2019, and entitled “SiₓN_{y} AS A NUCLEATION LAYER FOR SiCₓO_{y},” which is incorporated by reference herein in its entirety.

### TECHNICAL FIELD

The subject matter disclosed herein relates to methods of substrate processing used in the semiconductor and allied industries. More specifically, the disclosed subject matter relates to methods of depositing a silicon nitride nucleation layer substantially concurrently over combinations of dielectric and metal layers to avoid a substantial nucleation delay in a subsequently-deposited silicon carbide layer.

### BACKGROUND

Fabrication of semiconductor devices often involves depositions of layers of dielectric materials over metal materials. Examples of such dielectric layers include encapsulation layers for memory stacks, as well as various diffusion-barrier layers, and etch-stop layers. Silicon carbide (SiC) is one of type of dielectric material frequently used for such applications. Classes of SiC thin films include oxygen-doped silicon carbide, also known as silicon oxycarbide (SiCO or, more generally, SiCₓO_{y} (nitrogen-doped silicon carbide, also known as silicon nitricarbide, oxygen-doped and nitrogen-doped silicon carbide, also known as silicon oxynitricarbide, and undoped silicon carbide. Silicon carbide is typically deposited by chemical vapor deposition (CVD) processes, such as by plasma-enhanced chemical vapor deposition (PECVD) or, in some cases, by atomic-layer deposition (ALD) processes. Each of these deposition techniques is known in the art.

A person of ordinary shill in the art understands that the deposition of SiCₓO_{y}, or other dielectric films deposited on metals such as tungsten (W) and cobalt (Co), is slightly thinner than a deposition of SiCₓO_{y} on dielectric materials, such as SiN, which means there is a delay in the nucleation and growth of the SiCₓO_{y} on metals. This can become problematic in features that contain multiple materials in feature, as the SiCₓO_{y} thickness varies depending on the type of material that exists at that particular location. A variation in thickness can affect, for example, a sidewall profile of the feature, the material properties of the SiCₓO_{y} film (e.g., hermiticity, pinholes, wet and dry etch thicknesses, etc.) and can cause problems with subsequent device-integration steps. Current strategies to overcome the nucleation delay issue include:
(1) Surface treatment: Prior to deposition, the metal surface is treated using an H₂-based plasma or diborane-gas annealing process step. The mechanism is thought to change properties of the metal surface and promote a subsequent dielectric-film deposition; and
(2) SiO₂ Deposition: A silicon dioxide (SiO₂)-based initiation-layer is deposited to attempt to address the dielectric-growth nucleation-delay on metal surfaces (as described with reference to FIG. 2, below). The SiO₂-based solution decreases the differential thickness issue but not completely enough for advanced semiconductor devices. Also, this technique may be less robust when one or more properties of the metal surface have been changed by, for example, different etching and/or cleaning processes during device integration steps. Further, the SiO₂ process may cause a metal-oxide layer to form on the underlying metal material.

FIG. 1 shows an example of a cross-sectional semiconductor structure 100 having a silicon oxycarbide layer deposited over a combination of a dielectric material 101, a metal material 103, and a semiconductor material 105, in accordance with methods of the prior art. The cross-sectional semiconductor structure 100 may be, for example, a bitline as used in various types of non-volatile memory devices. The silicon oxycarbide may be used to form a low dielectric-constant (low-κ) spacer over the cross-sectional semiconductor structure 100. However, for bitline applications as well as numerous other types of applications, the thickness of silicon oxycarbide (e.g., a spacer) over the various materials should have a substantially constant thickness. In this example, the dielectric material 101 may be silicon nitride (SIN), the metal material 103 may be tungsten (W), and the semiconductor material 105 may be silicon (Si).

With continuing reference to FIG. 1, the semiconductor structure 100 has a first silicon-oxycarbide layer 107 formed over the dielectric material 101, where the first silicon oxycarbide layer 107 has a first thickness, t₁; a second silicon-oxycarbide layer 109 formed over the metal material 103 having a second thickness, t₂; and a third silicon-oxycarbide layer 111 formed over the semiconductor material 105 having a third thickness, t₃. As shown in FIG. 1, the third thickness, t₃, of the third-silicon oxycarbide layer 111 is approximately the same thickness as the first thickness, t₁, of the first silicon-oxycarbide layer 107. However, the second thickness, t₂, of the second-silicon oxycarbide 109 is substantially thinner than either the first thickness t₁ or the third thickness t₃.

One reason the second silicon-oxycarbide layer 109 is thinner is due to nucleation differences of the silicon oxycarbide deposited on the metal material 103. The nucleation differences are due to a difference in availability of reaction sites for the silicon oxycarbide in comparison with the silicon-oxycarbide layers 107, 111 formed over the dielectric material 101 and the semiconductor material 105, respectively. Another reason for the difference in thicknesses of the respective silicon-oxycarbide layers 107, 109, 111 may be due to different chemical contamination levels on the three materials 101, 103, 107. Regardless of the cause, the non-uniformity on thickness of the silicon-oxycarbide layers can be detrimental to many types of semiconductor devices. In some cases, the non-uniformity of thicknesses may make the semiconductor device slower, unstable, or affect device performance in other ways. In some cases, the non-uniformity of thicknesses may make the semiconductor device completely unusable.

FIG. 2 shows a cross-sectional semiconductor structure 200 having a silicon dioxide (SiO₂) initiation-layer 213 to reduce a thickness difference between a thickness of silicon oxycarbide deposited over a dielectric material 201, deposited over a metal material 203, and deposited over a semiconductor material 205, in accordance with methods of the prior art. In one embodiment, the SiO₂ initiation-layer 213 may be a conformally-deposited ALD layer. The cross-sectional semiconductor structure 200 may be similar to or the same as the cross-sectional semiconductor structure 100 of FIG. 1. In this example, the dielectric material 201 may be silicon nitride (SiN), the metal material 103 may be tungsten (W), and the semiconductor material 105 may be polysilicon.

The semiconductor structure 200 has a first silicon-oxycarbide layer 207 formed over the dielectric material 201, where the first silicon-oxycarbide layer has a first thickness, t₁; a second silicon-oxycarbide layer 209 formed over the metal material 203 having second thickness, t₂; and a third silicon-oxycarbide layer 211 formed over the polysilicon material 205 having a third thickness, t₃. The third thickness, t₃, of the third silicon-oxycarbide layer 211 is approximately the same thickness as the first thickness, t₁, of the first silicon-oxycarbide layer 207. The second thickness, t₂, of the second silicon-oxycarbide 209 is thinner than either the first thickness t₁ or the third thickness t₃. However, unlike the second silicon-oxycarbide 109 of the semiconductor structure 100 of FIG. 1, the thickness of the second silicon-oxycarbide 209 of FIG. 2 is much closer to the thicknesses of the other two silicon-oxycarbide layers 207, 211.

Consequently, the SiO₂ initiation-layer 213 at least partially addresses the dielectric-growth nucleation-delay on metal surfaces as discussed above. However, the SiO₂ initiation-layer 213 solution may be less robust when one or more properties of the metal surface have been changed by different etching and/or cleaning processes experienced by the semiconductor structure 200 during, for example, device integration steps. Therefore, even though the difference in thickness (Δt) using the SiO₂ initiation-layer 213 has greatly reduced the differential thickness difference, many contemporaneous semiconductor devices today require a Δt of less than about 2 mm to about 3 nm.

The information described in this section is provided to offer the skilled artisan a context for the following disclosed subject matter and should not be considered as admitted prior art.

### SUMMARY

In one exemplary embodiment, the disclosed subject matter describes a method to produce a substantially uniform, silicon-carbide layer over both of at least one dielectric material and at least one metal material substantially concurrently. The method includes forming a silicon-nitride layer, in the form of SixNy, over the at least one dielectric material and the at least one metal material, and forming the silicon-carbide layer, in the form of SiCxOy, over the silicon-nitride layer.

In an exemplary embodiment, the disclosed subject matter describes a method for forming a silicon-carbide layer. The method includes forming a silicon nitride initiation-layer, in the form of SixNy, substantially simultaneously over at least a dielectric material and a metal material. The silicon nitride initiation-layer is to serve as a growth-initiation layer. The silicon-carbide layer, in the form of SiCxOy, is formed over the silicon nitride initiation-layer. The formed silicon nitride initiation-layer is to substantially prevent a delay in a nucleation and growth of the silicon-carbide layer on the metal material in comparison with a nucleation and growth of the silicon-carbide layer on the dielectric material.

In an exemplary embodiment, the disclosed subject matter describes a method for forming a silicon-carbide layer. The method includes forming layers of at least one metal material and at least one dielectric material in a deposition chamber on a substrate, forming silicon nitride in the form of SixNy as an initiation-layer over the at least one metal material and the at least one dielectric material on the substrate, and subsequently forming at least one layer over the silicon nitride where the at least one layer includes materials selected from materials including silicon carbide, in the form of SixCy, silicon carbon nitride, in the form of SixCyNz, silicon oxycarbonitride, in the form of SiCxNyOz, and silicon oxycarbide, in the form of SixCyOz.

### BRIEF DESCRIPTION OF THE FIGURES

FIG. 1 shows a cross-sectional semiconductor structure having silicon oxycarbide deposited over a combination of a dielectric material, a metal material, and a semiconductor material, in accordance with methods of the prior art;

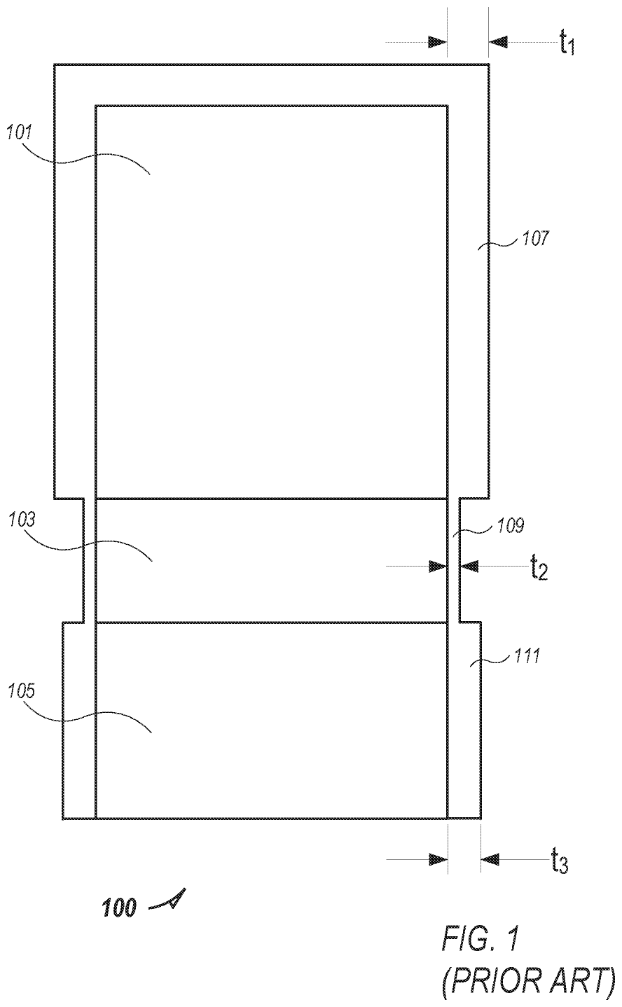

FIG. 2 shows a cross-sectional semiconductor structure having an silicon dioxide (SiO₂) initiation-layer to reduce a thickness difference between a thickness of silicon oxycarbide deposited over a dielectric material, deposited over a metal material, and deposited over a semiconductor material, in accordance with methods of the prior art;

FIG. 3 shows an example of a cross-sectional semiconductor structure having a silicon nitride (SiN) initiation-layer formed substantially simultaneously formed over a dielectric material, a metal material, and a polysilicon material, in accordance with the disclosed subject matter;

FIG. 4 shows an exemplary process flow to prepare the SiN initiation-layer for forming over various types of material;

FIG. 5 shows an example of a cross-sectional schematic diagram of a remote-plasma apparatus with a processing chamber that may be used with various embodiments disclosed herein; and

FIG. 6 shows a simplified block diagram of a machine in an example form of a computing system within which a set of instructions for causing the machine to perform any one or more of the methodologies and operations (e.g., process recipes) discussed herein may be executed.

### DETAILED DESCRIPTION

The disclosed subject matter will now be described in detail with reference to a few general and specific embodiments as illustrated in various ones of the accompanying drawings. In the following description, numerous specific details are set forth in order to provide a thorough understanding of the disclosed subject matter. It will be apparent, however, to one skilled in the art, that the disclosed subject matter may be practiced without some or all of these specific details. In other instances, well-known process steps, fabrication techniques, or structures have not been described in detail so as not to obscure the disclosed subject matter.

Manufacture of semiconductor devices typically involves depositing one or more thin films on a substrate in an integrated-fabrication process. In some aspects of the integrated-fabrication process, various types of thin films can be deposited using atomic layer deposition (ALD), chemical vapor deposition (CVD), plasma-enhanced chemical vapor deposition (PECVD), or any other suitable deposition methods and techniques as described above.

PECVD processes may use in-situ plasma processing for the deposition of silicon carbide classes of thin films, where the plasma processing occurs directly adjacent to a substrate. However, it has been found that depositing high-quality silicon carbide classes of thin films can have several challenges. For example, such challenges can include providing silicon carbide classes of thin films with excellent step coverage, low dielectric-constants, high breakdown-voltages, low leakage-currents, low porosity, high hermeticity, high density, high hardness, and coverage over exposed metal surfaces without oxidizing the metal surfaces, among other factors.

The silicon-carbide films described herein may include both doped and undoped silicon carbide, such as doped and undoped versions of SiₓC_{y}, silicon carbon nitride (SiₓC_{y}N_{z}), silicon oxycarbonitride (SiCₓN_{y}O_{z}), and silicon oxycarbide (SiₓC_{y}O_{z}) of varying stoichiometries (the formulas indicate various elemental compositions, but the stoichiometry can vary). Hydrogen may optionally be present in any of the silicon-carbide films (e.g., SiₓC_{y}, SiₓC_{y}N_{z}, SiCₓN_{y}O_{z}, and SiₓC_{y}O_{z} films).

In various embodiments, for the deposition processes described herein, a plasma is formed directly in the process chamber or process-chamber compartment that houses the substrate. However, while this disclosure is not limited by any particular theory, the plasma conditions in typical PECVD processes may produce undesirable effect. For example, the PECVD process may provide direct plasma conditions that break the Si—N and/or Si—C bonds in the precursor molecules. Direct plasma conditions can include charged particle bombardment and high-energy ultraviolet radiation, which can result in damaging effects in the thin film.

One such film-damaging effect resulting from direct plasma conditions can include poor step coverage. The charged particles in direct plasma conditions can lead to highly reactive radicals with increased sticking coefficients. A deposited silicon carbide film may have silicon, carbon, oxygen, and/or nitrogen bonds that are “dangling,” meaning that the silicon, carbon, and/or nitrogen atoms will have reactive, unpaired valence electrons. The increased sticking coefficients of precursor molecules can lead to deposition of silicon-carbide films with poor step coverage, as reactive precursor fragments may tend to stick to sidewalls of previously deposited films or layers.

Another film-damaging effect that may result from direct plasma conditions can include directionality in the deposition. This is due in part to the energy required to break up the precursor molecules can be at a low frequency, which creates a significant amount of ion bombardment at the surface. Directional deposition may further lead to depositions with poor step coverage.

Direct-plasma conditions in PECVD may also lead to increased production of silicon-hydrogen bonding (Si—H) in the silicon carbide film. Specifically, broken bonds of Si—C can be replaced with Si—H. This type of bonding can result in not only a reduced carbon content but may also result in films with poor electrical properties in some instances. For example, the presence of Si—H bonds can reduce breakdown voltages and increase leakage currents because the Si—H bonds provide a leakage path for electrons.

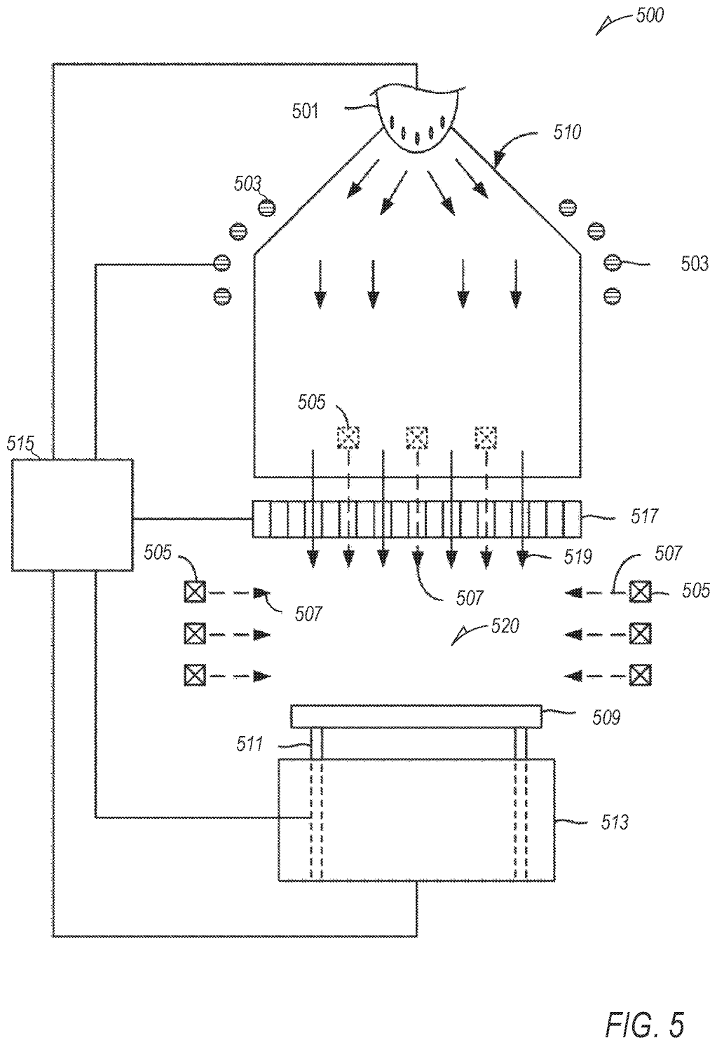

Consequently, due to the potential disadvantages of direct plasma types of processing, many of the techniques described herein rely on remote-plasma techniques, and especially, remote-plasma ALD techniques. In a remote-plasma technique in general, the plasma is formed remotely in a chamber that is different from the chamber that is housing the substrate. The plasma is then transferred to the chamber housing the substrate. This remote-plasma process is described in more detail with reference to FIG. 5, below. In various embodiments, the plasma is formed using a frequency in a range of between about 2.45 MHz to about 13.56 MHz, with power in a range of between about 2 kW to about 6 kW. In some embodiments pressure in the chamber is less than about 2 Torr, such as about 1.5 Torr or less. As is known to a person of ordinary skill in the art, lower pressures are often associated with higher deposition rates. However, in appropriate conditions and with appropriate safeguards, the disclosed subject matter can be applicable to direct-plasma techniques, described above, as well.

In general, and as described briefly above, modern advanced semiconductor devices, such as memory and logic integrations, require uniform depositions of spacer film formed on different materials including, for example, silicon, metal, and dielectric materials. However, due to differences in material properties, a spacer film deposited by techniques such as ALD and CVD, often show different nucleation behaviors between, for example, metal surfaces and dielectric surfaces. The different nucleation behaviors lead to different deposition thicknesses. Various embodiments of the disclosed subject matter address this specific issue.

In various embodiments described herein, the deposition of a silicon nitride (or more generally, SiₓN_{y}) layer on a metal surface or on a dielectric surface enables a subsequent deposition of a silicon oxycarbide (or more generally, SiCₓO_{y}) layer without a substantial delay of SiCₓO_{y} nucleation and growth. The SiₓN_{y} layer may be deposited in situ using, for example, a plasma-enhanced atomic-layer deposition (PEALD) process. The PEALD process occurs in the same chamber immediately prior to the remote-plasma chemical vapor deposition of SiCₓO_{y}. The presumably uniform and non-selective coating of the SiₓN_{y} on the metal surfaces and the dielectric surfaces allows the SiCₓO_{y} to deposit on SiₓN_{y} rather than a metal surface, where the SiCₓO_{y} would otherwise experience a nucleation delay. Therefore, a uniform thickness of SiCₓO_{y} is deposited on the feature regardless of the material (e.g., metal or dielectric) present. The PEALD process for depositing SiₓN_{y} has been shown to be effective on, for example, SiN, polycrystalline silicon, and tungsten metal. After the deposition of SiN, the SiCₓO_{y} deposition on these materials is substantially equivalent with little to no differential thickness difference in the deposited SiCₓO_{y} regardless of the material underlying the SiN layer.

This strategy of using an ALD of SiN prior to the deposition of SiCₓO_{y} can likely be extended to ensure uniform depositions of SiCₓO_{y} on other dielectric materials and metal materials (e.g., cobalt (Co), copper (Cu), and ruthenium (Ru)) in the semiconductor and allied industries. The ALD SiₓN_{y} serves as the growth-initiation layer.

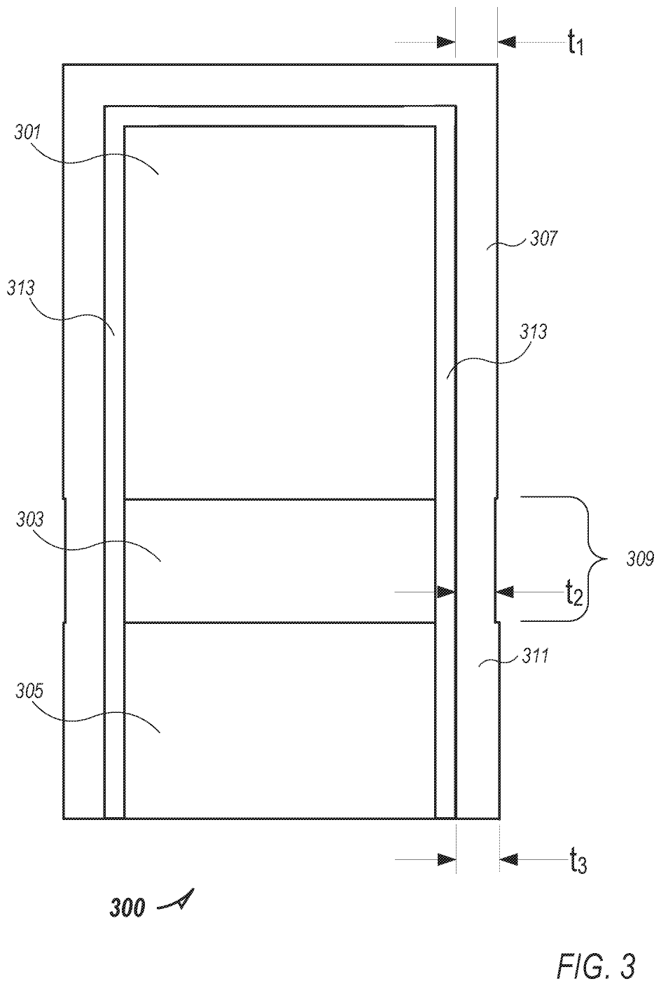

For example, with reference now to FIG. 3, a cross-sectional semiconductor structure 300 having a silicon nitride (e.g., SiₓN_{y}) initiation-layer 313 to reduce a thickness difference between a thickness of silicon oxycarbide (e.g., SiCₓO_{y}) deposited over a dielectric material 301, deposited over a metal material 303, and deposited over a semiconductor material 305, in accordance with various embodiments described herein. In a specific exemplary embodiment, the SN initiation layer 313 may be a conformally-deposited ALD layer. In this example, the dielectric material 301 may be silicon nitride (SiN), the metal material 303 may be tungsten (W), and the semiconductor material 305 may be polysilicon.

In various embodiments, the dielectric material 301 may comprise, for example, silicon dioxide (SiO₂), silicon nitride (SiₓN_{y}) or a variety of other dielectric materials or ceramics such as tantalum pentoxide (Ta₂O₅), aluminum oxide (Al₂O₃), hafnium oxide (HfO₂), zirconium dioxide (ZrO₂), lanthanum oxide (LaₓO_{y}), strontium titanate (SrTiO₃), strontium oxide (SrO), or combinations of these and other dielectric materials.

In various embodiments, the metal material 303 may include a variety of metals, such as tungsten (W), titanium (Ti), tantalum (Ta), cobalt (Co), copper (Cu), platinum (Pt), and other elemental metals, and alloys thereof, known and used in the art. In various embodiments, the semiconductor material 305 may comprise silicon (including polycrystalline silicon), germanium, and other elemental and compound semiconductor materials known and used in the art.

With reference again to FIG. 3, generally, the cross-sectional semiconductor structure 300 may comprise planar features (oriented either vertically or horizontally with reference to a surface on an underlying substrate) or may include recessed or protruding features. The methods provided herein are particularly advantageous for structures having recessed features, because they allow for a conformal and uniform deposition of silicon carbide, even when thin layers need to be deposited. The disclosed subject matter can be used for depositing silicon carbide layers having a variety of thicknesses (e.g., about 20 Å to about 400 Å), and are particularly advantageous for depositing thin silicon carbide layers (e.g., having thicknesses of about 20 Å to about 100 Å).

The semiconductor structure 300 has a first silicon-oxycarbide layer 307 formed over the dielectric material 301 where the first silicon-oxycarbide layer has a first thickness, t₁; a second silicon-oxycarbide layer 309 formed over the metal material 303 having a second thickness, t₂; and a third silicon-oxycarbide layer 311 formed over the semiconductor material 305 having a third thickness, t₃. The third thickness, t₃, of the third silicon-oxycarbide layer 311 is approximately the same thickness as the first thickness, t₁, of the first silicon-oxycarbide layer 307. The second thickness, t₂, of the second silicon oxycarbide 307 is also approximately the same thickness as either the first thickness t₁ or the third thickness t₃. In tests applying techniques of the disclosed subject matter, the differential thickness between the first thickness, t₁, the second thickness, t₂, and the third thickness, t₃, has been unmeasurable. Therefore, the differential thickness of the deposited silicon-oxycarbide layer has been well within about 2 nm (i.e., less than about 2 nm.

However, even though the disclosed subject matter has been defined with reference to the semiconductor structure 300, upon reading and understanding the disclosed subject matter, a person of ordinary skill in the art will recognize that the disclosed subject matter may be applied to any vertical structure (e.g., a vertical orientation with reference to the structure being substantially perpendicular to an underlying substrate, not shown) or horizontal (e.g., a horizontal orientation with reference to the structure being substantially parallel to the substrate), or any other orientation with reference to the substrate.

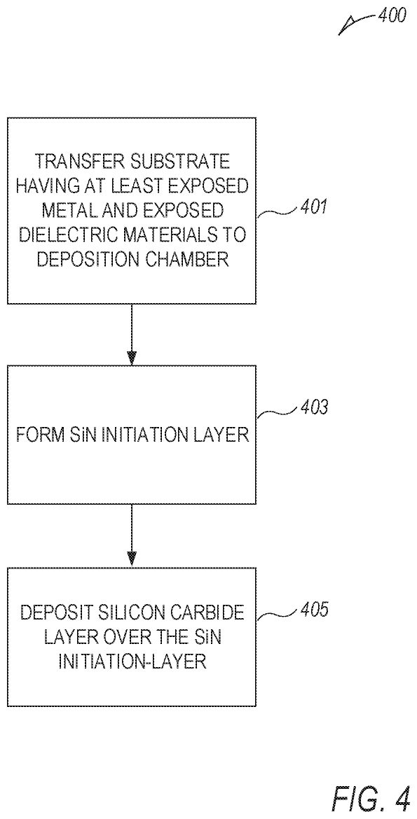

With reference now to FIG. 4, an exemplary process flow 400 to prepare the SiₓN_{y} initiation-layer for forming over various types of material is shown. A substrate having exposed layers of at least one metal material and at least one dielectric material is transferred to a deposition chamber at operation 401. To enable a substantially uniform deposition of SiCₓO_{y} on various dielectric and metal materials (as well as other materials, such as, for example, a semiconductor material), an initiation layer in the form of, for example, PEALD SiₓN_{y} is deposited or otherwise formed over the various dielectric and metal materials at operation 403. As noted above, the SiₓN_{y} deposits substantially uniformly on dielectric materials, metal materials, and semiconductor materials to within, at least, metrology detection limits (e.g., less than about a 2 nm differential step height in the SiₓN_{y} formed over the dielectric versus the SiₓN_{y} formed over the metal). At operation 405, an SiCₓO_{y} layer is subsequently deposited or otherwise formed over the SiₓN_{y} layer.

Consequently, to prevent nucleation delay of SiCₓO_{y} growth on different materials that may exist in a feature, a thin layer of SiₓN_{y} is first deposited. In embodiments, the SiₓN_{y} may be deposited in the same chamber as the subsequent SiCₓO_{y} deposition (e.g., direct plasma). In other embodiments, the SiₓN_{y} may be deposited in a different chamber then the subsequent SiCₓO_{y} deposition (e.g., remote plasma). In various embodiments, the SiₓN_{y} may be deposited or otherwise formed in thicknesses from, for example, about 20 nm to about 200 nm. However, these thicknesses are exemplary only and thickness ranges less than about 20 nm or greater than about 200 nm may also be considered for a given process.

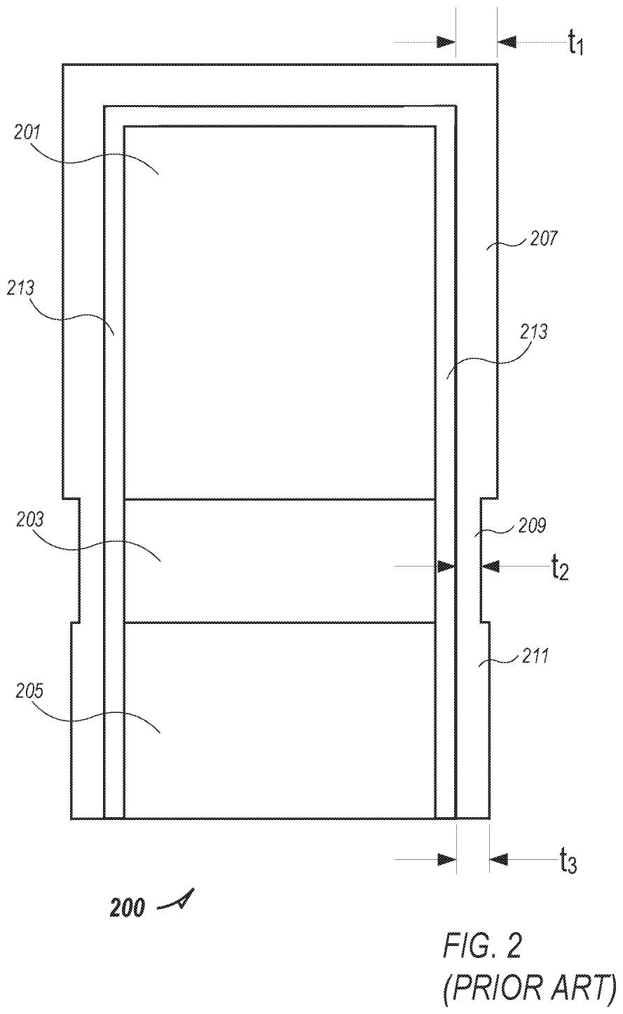

The use of SiₓN_{y} as the initiation layer for the SiCₓO_{y} deposition process has advantages over the prior-art process that relied on, for example, using an SiO₂ initiation-layer, as described above with reference to FIG. 2. For example, using SiₓN_{y} as the initiation layer does not oxidize the underlying metal onto which it deposits as occurs with the SiO₂ initiation-layer process. The lack of oxidation is advantageous since the oxidation of the metal may increase the resistance of that metal material (e.g., a metal line or via). The increased resistance can result in, for example, decreased switching speed of electronic devices. While there is a chance that the underlying metal material may form a nitride at a surface of the metal, the resistance of metal nitrides is generally lower than that of metal oxides. Consequently, the effect on device speed would not be as severe as that of forming an oxide on the surface of the metal. Another advantage of using SiₓN_{y} as the initiation layer instead of etch and wet clean steps to clean up the surface of the metal and dielectric materials, is that it saves time due to a reduced number of process steps. The reduced number of process steps further translates to reduced production costs. Moreover, the SiₓN_{y} initiation-layer is generally more robust than an SiO₂ initiation-layer. Overall, use of SiₓN_{y} as the initiation layer for the SiCₓO_{y} deposition process generates a better post-deposition profile, as shown and described with reference to FIG. 3, above, and further generates a higher device yield of semiconductor devices.

### Remote Plasma Apparatus

As described above, in various embodiments the disclosed subject matter may use a remote-plasma apparatus. As described in more detail below, the remote-plasma apparatus includes a processing chamber, a substrate support for holding the substrate in the processing chamber, a remote plasma source over the substrate support, a showerhead between the remote plasma source and the substrate support, one or more movable members in the processing chamber, and a controller. The one or more movable members may be configured to move the substrate to positions between the showerhead and the substrate support. The controller may be configured to perform one or more operations, including transporting the substrate to the processing chamber, transporting the substrate to the substrate support, and forming a remote plasma of a gas.

FIG. 5 shows an example of a cross-sectional schematic diagram of a remote-plasma apparatus 500 with a processing chamber in accordance with various exemplary embodiments. The remote-plasma apparatus 500 includes a processing chamber 520, which includes a substrate support 513, such as a pedestal or electrostatic chuck (ESC), to support a substrate 509. In various embodiments, the substrate may be a silicon wafer. The remote-plasma apparatus 500 also includes a remote-plasma source 510 over the processing chamber 520, and a showerhead 517 located between the substrate 509 and the remote-plasma source 510.

A gas species 519 can flow from the remote-plasma source 510 towards the substrate 509 through the showerhead 517. A remote plasma may be generated in the remote-plasma source 510 to produce radicals of a chosen version of the gas species 519. The remote plasma may also produce ions and other charged species of the gas species 519. The remote plasma may further generate photons, such as UV radiation, from the gas species 519. For example, coils 503 may surround the walls of the remote-plasma source 510 and generate a remote plasma in the remote-plasma source 510.

In some embodiments, the coils 503 may be in electrical communication with a radio-frequency (RF) power source or microwave power source (not shown). A commercial example of a remote-plasma source 510 with an RF-power source is the GAMMA® remote-plasma generator product family, manufactured by Lam Research Corporation of Fremont, Calif., USA. Another example of an RF-remote plasma source is the Astron® remote-plasma generator, manufactured by MKS Instruments of Wilmington, Mass., USA, which can be operated at 440 kHz and can be provided as a subunit, bolted onto or otherwise attached, to a larger apparatus for processing one or more substrates in parallel. In some embodiments, a microwave-plasma source can be used with the remote plasma source 540, as found in the Astex® microwave-plasma source, also manufactured by MKS Instruments. A microwave-plasma source can be configured to operate at a frequency of, for example, 2.45 GHz.

Any type of plasma source may be used in the remote-plasma source 510 to create radical species. These plasma types include, for example, capacitively-coupled plasmas, microwave plasmas, DC plasmas, inductively-coupled plasmas, and laser-created plasmas. An example of a capacitively coupled plasma can be a radio-frequency (RF) plasma.

In embodiments with an RF-power source, the RF generator may be operated at any suitable power to form a plasma of a desired composition of radical species. Examples of suitable powers include, but are not limited to, powers between about 0.5 kW and about 6 kW. Likewise, the RF generator may provide RF power of a suitable frequency, such as 13.56 MHz for an inductively-coupled plasma.

The gas species 519 may be delivered from a gas inlet 501 and into an internal volume of the remote-plasma source 510. Power supplied to the coils 503 can generate a remote plasma with the gas species 519 to form radicals of the gas species 519. The radicals formed in the remote-plasma source 510 can be carried, in the gas phase, towards the substrate 509 through the showerhead 517.

With continuing reference to FIG. 5, the remote-plasma apparatus 500 may actively cool or otherwise control the temperature of the substrate 509. In some embodiments, it may be desirable to control the temperature of the substrate 509 to control a rate of a reaction and a uniformity of exposure to the remote plasma during processing.

In various embodiments, the remote-plasma apparatus 500 can include movable members 511, such as lift pins, that are capable, of moving the substrate 509 away from or towards the substrate support 513. The movable members 511 can be configured to extend between from, for example, about 0 mm to about 125 mm, or more, away from the substrate support 513. In an exemplary embodiment, the movable members 511 can extend the substrate 509 away from the substrate support 513, which is hot, towards the showerhead 517, which is cooler, to cool the substrate 509. The movable members 511 can also be retracted to bring the substrate 509 towards the hotter substrate support 513, and away from the cooler showerhead 517, to heat the substrate 509. By positioning the substrate 509 via the movable members 511, the temperature of the substrate 509 can be adjusted. In some embodiments, when positioning the substrate 509, the showerhead 517 and the substrate support 513 can be held at a constant temperature.

In some embodiments, the remote-plasma apparatus 500 can include a type of showerhead that includes temperature control of the showerhead 517. For example, to permit active cooling of the showerhead 517, a heat-exchange fluid may be used, such as deionized water or a thermal-transfer liquid. One such thermal-transfer liquid is manufactured by the Dow Chemical Company of Midland, Mich., USA. In some embodiments, the heat-exchange fluid may flow through fluid channels (not shown) in the showerhead 517. In addition, the showerhead 517 may use a heat exchanger system (not shown), such as a fluid heater/chiller unit (known in the art) to control temperature. In some embodiments, the temperature of the showerhead 517 may be controlled to below about 30° C., such as between about 5° C. and about 20° C. The showerhead 517 may be cooled to lower the temperature of the substrate 509, such as before and after processing the substrate 509.

In some embodiments, the remote-plasma apparatus 500 can include one or more gas inlets 505 to flow a cooling gas 507 through the processing chamber 520. The one or more gas inlets 505 may be positioned above, below, and/or to the side of the substrate 509. Some of the one or more gas inlets 505 may be configured to flow the cooling gas 507 in a direction that is substantially perpendicular to a face of the substrate 509. In some embodiments, at least one of the gas inlets 505 may deliver the cooling gas 507 through the showerhead 517 to the substrate 509. A flow rate of the cooling gas 507 for cooling the substrate 509 may be between about 0.1 standard liters per minute (slpm) to about 100 slpm.

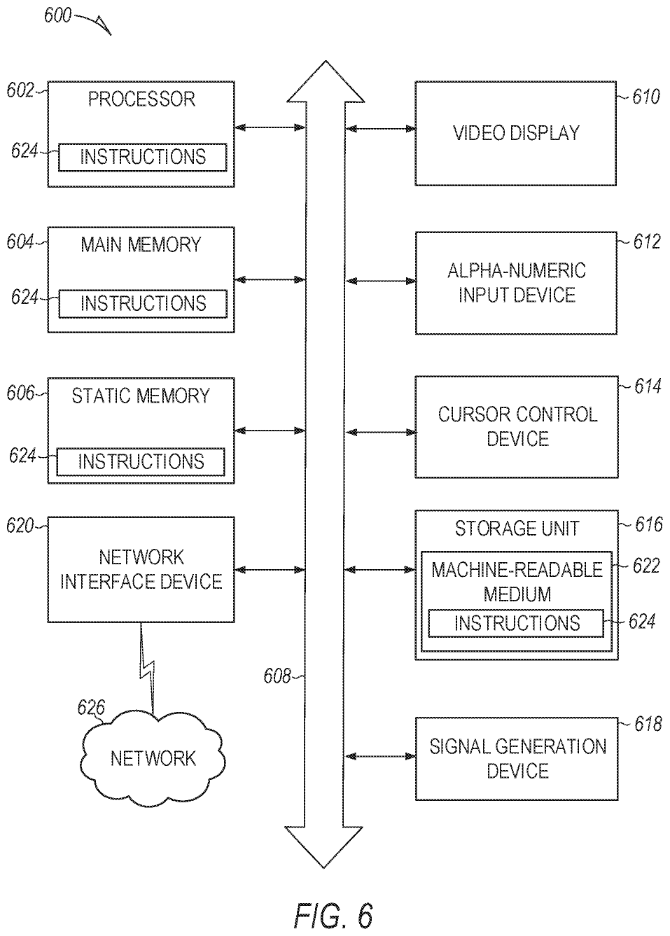

A controller 515 (described in more detail with reference to FIG. 6, below) may contain instructions for controlling parameters for the operation of the remote-plasma apparatus 500. In various embodiments, the controller 515 will typically include one or more memory devices and one or more processors. The processor may include a central-processing unit (CPU), microprocessor, or computer; analog and/or digital input/output connections; stepper-motor controller boards; and other connections and peripheral devices known in the art.

The controller 515 may contain instructions for controlling process conditions and operations (e.g., a process recipe) in accordance with various embodiments of the disclosed subject matter for the remote-plasma apparatus 500. In some embodiments, the controller 515 controls all of activities of a process tool (not shown). As described below with reference to FIG. 6, the controller 515 may execute system control software stored in a mass storage device, loaded into a memory device, and executed on a processor. The system control software may include instructions for controlling the timing, mixture of gases, chamber and/or station pressures, chamber and/or station temperatures, purge conditions and timing, substrate temperatures, RF-power levels, and RF frequencies. The system control software may also control substrate, pedestal, chuck and/or susceptor positions, and other parameters of a particular process, performed by the process tool. The system control software may be configured in any suitable way. For example, various process tool component subroutines or control objects may be written to control operations of the process tool components necessary to carry out various process tool processes in accordance with the disclosed methods. The system control software may be coded in any suitable computer readable programming language.

Machines with Instructions to Perform Various Operations

FIG. 6 is a block diagram illustrating components of a machine 600, according to some embodiments, able to read instructions from a machine-readable medium e.g., a non-transitory machine-readable medium, a machine-readable storage medium, a computer-readable storage medium, or any suitable combination thereof) and perform any one or more of the methodologies discussed herein. Specifically, FIG. 6 shows a diagrammatic representation of the machine 600 in the example form of a computer system and within which instructions 624 (e.g., software, a program, an application, an applet, an app, or other executable code) for causing the machine 600 to perform any one or more of the methodologies discussed herein (e.g., a process recipe) may be executed.

In alternative embodiments, the machine 600 operates as a standalone device or may be connected (e.g., networked) to other machines. In a networked deployment, the machine 600 may operate in the capacity of a server machine or a client machine in a server-client network environment, or as a peer machine in a peer-to-peer (or distributed) network environment. The machine 600 may be a server computer, a client computer, a personal computer (PC), a tablet computer, a laptop computer, a netbook, a set-top box (STB), a personal digital assistant (PDA), a cellular telephone, a smartphone, a web appliance, a network router, a network switch, a network bridge, or any machine capable of executing the instructions 624, sequentially or otherwise, that specify actions to be taken by that machine. Further, while only a single machine is illustrated, the term “machine” shall also be taken to include a collection of machines that individually or jointly execute the instructions 624 to perform any one or more of the methodologies discussed herein.

The machine 600 includes a processor 602 (e.g., a central processing unit (CPU), a graphics processing unit (CPU), a digital signal processor (DSP), an application specific integrated circuit (ASIC), a radio-frequency integrated circuit (RFIC), or any suitable combination thereof), a main memory 604, and a static memory 606, which are configured to communicate with each other via a bus 608. The processor 602 may contain microcircuits that are configurable, temporarily or permanently, by some or all of the instructions 624 such that the processor 602 is configurable to perform any one or more of the methodologies described herein, in whole or in part. For example, a set of one or more microcircuits of the processor 602 may be configurable to execute one or more modules (e.g., software modules) described herein.

The machine 600 may further include a graphics display 610 (e.g., a plasma display panel (PDP), a light emitting diode (LED) display, a liquid crystal display (LCD), a projector, or a cathode ray tube (CRT)). The machine 600 may also include an alpha numeric input device 612 (e.g., a keyboard), a cursor control device 614 (e.g., a mouse, a touchpad, a trackball, a joystick, a motion sensor, or other pointing instrument), a storage unit 616, a signal generation device 618 (e.g., a speaker), and a network interface device 620.

The storage unit 616 includes a machine-readable medium 622 (e.g., a tangible and/or non-transitory machine-readable storage medium) on which is stored the instructions 624 embodying any one or more of the methodologies or functions described herein. The instructions 624 may also reside, completely or at least partially, within the main memory 604, within the processor 602 (e.g., within the processor's cache memory), or both, during execution thereof by the machine 600. Accordingly, the main memory 604 and the processor 602 may be considered as machine-readable media (e.g., tangible and/or non-transitory machine-readable media). The instructions 624 may be transmitted or received over a network 626 via the network interface device 620. For example, the network interface device 620 may communicate the instructions 624 using any one or more transfer protocols (e.g., hypertext transfer protocol (HTTP)).

In some embodiments, the machine 600 may be a portable computing device, such as a smart phone or tablet computer, and have one or more additional input components (e.g., sensors or gauges). Examples of such additional input components include an image input component (e.g., one or more cameras), an audio input component (e.g., a microphone), a direction input component (e.g., a compass), a location input component (e.g., a global positioning system (GPS) receiver), an orientation component (e.g., a gyroscope), a motion detection component (e.g., one or more accelerometers), an altitude detection component (e.g., an altimeter), and a gas detection component (e.g., a gas sensor). Inputs harvested by any one or more of these input components may be accessible and available for use by any of the modules described herein.

As used herein, the term “memory” refers to a machine-readable medium able to store data temporarily or permanently and may be taken to include, but not be limited to, random-access memory (RAM), read-only memory (ROM), buffer memory, flash memory, and cache memory. While the machine-readable medium 622 is shown in an embodiment to be a single medium, the term “machine-readable medium” should be taken to include a single medium or multiple media (e.g., a centralized or distributed database, or associated caches and servers) able to store instructions. The term “machine-readable medium” shall also be taken to include any medium, or combination of multiple media, that is capable of storing instructions for execution by a machine (e.g., the machine 600), such that the instructions, when executed by one or more processors of the machine (e.g., the processor 602), cause the machine to perform any one or more of the methodologies described herein. Accordingly, a “machine-readable medium” refers to a single storage apparatus or device, as well as “cloud-based” storage systems or storage networks that include multiple storage apparatus or devices. The term “machine-readable medium” shall accordingly be taken to include, but not be limited to, one or more tangible (e.g., non-transitory) data repositories in the form of a solid-state memory, an optical medium, a magnetic medium, or any suitable combination thereof.

Furthermore, the machine-readable medium is non-transitory in that it does not embody a propagating signal. However, labeling the tangible machine-readable medium as “non-transitory” should not be construed to mean that the medium is incapable of movement—the medium should be considered as being transportable from one physical location to another. Additionally, since the machine-readable medium is tangible, the medium may be considered to be a machine-readable device.

The instructions 624 may further be transmitted or received over a network 626 (e.g., a communications network) using a transmission medium via the network interface device 620 and utilizing any one of a number of well-known transfer protocols (e.g., HTTP). Examples of communication networks include a local area network (LAN), a wide area network (WAN), the Internet, mobile telephone networks, POTS networks, and wireless data networks (e.g., WiFi and WiMAX networks). The term “transmission medium” shall be taken to include any intangible medium that is capable of storing, encoding, or carrying instructions for execution by the machine, and includes digital or analog communications signals or other intangible medium to facilitate communication or such software.

Overall, the disclosed subject matter contained herein describes or relates generally to depositing of otherwise forming uniform thickness layers of silicon carbide, in the various forms as discussed above. However, the disclosed subject matter is not limited to semiconductor fabrication environments and can be used in a number of other environments. Upon reading and understanding the disclosure provided herein, a person of ordinary skill in the art will recognize that various embodiments of the disclosed subject matter may be used with other types of process tools as well as a wide variety of other tools, equipment, and components.

As used herein, the term “or” may be construed in an inclusive or exclusive sense. Further, other embodiments will be understood by a person of ordinary skill in the art upon reading and understanding the disclosure provided. Further, upon reading and understanding the disclosure provided herein, the person of ordinary skill in the art will readily understand that various combinations of the techniques and examples provided herein may all be applied in various configurations.

Although various embodiments are discussed separately, these separate embodiments are not intended to be considered as independent techniques or designs. As indicated above, each of the various portions may be inter-related and each may be used separately or in combination with other embodiments discussed herein. For example, although various embodiments of methods, operations, and processes have been described, these methods, operations, and processes may be used either separately or in various combinations.

Consequently, many modifications and variations can be made, as will be apparent to a person of ordinary skill in the art upon reading and understanding the disclosure provided herein. Further, functionally equivalent methods and devices within the scope of the disclosure, in addition to those enumerated herein, will be apparent to the skilled artisan from the foregoing descriptions. Portions and features of some embodiments, materials, and construction techniques may be included in, or substituted for, those of others. Such modifications and variations are intended to fall within a scope of the appended claims. Therefore, the present disclosure is to be limited only by the terms of the appended claims, along with the full scope of equivalents to which such claims are entitled. It is also to be understood that the terminology used herein is for the purpose of describing particular embodiments only and is not intended to be limiting.

The Abstract of the Disclosure is provided to allow the reader to quickly ascertain the nature of the technical disclosure. The abstract is submitted with the understanding that it will not be used to interpret or limit the claims. In addition, in the foregoing Detailed Description, it may be seen that various features may be grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

### THE FOLLOWING NUMBERED EXAMPLES ARE SPECIFIC EMBODIMENTS OF THE DISCLOSED SUBJECT MATTER

Example 1: In an exemplary embodiment, the disclosed subject matter is a method to produce a substantially uniform, silicon-carbide layer over both of at least one dielectric material and at least one metal material substantially concurrently. The method includes forming a silicon-nitride layer, in the form of SiₓN_{y}, over the at least one dielectric material and the at least one metal material, and forming the silicon-carbide layer, in the form of SiₓCₓO_{y}, over the silicon-nitride layer.

Example 2: The method of Example 1, wherein the formed silicon-nitride layer is substantially to prevent a delay in a nucleation and growth of the silicon-carbide layer on the at least one metal material in comparison with a nucleation and growth of the silicon-carbide layer on the at least one dielectric material.

Example 3: The method of any one of the preceding Examples, wherein the silicon-carbide layer further comprises hydrogen.

Example 4: The method of any one of the preceding Examples, further comprising forming the silicon nitride layer over a semiconductor material.

Example 5: The method of any one of the preceding Examples, wherein the at least one metal material comprises at least one material selected from materials including tungsten (W), titanium (Ti), tantalum (Ta), cobalt (Co), copper (Cu), platinum (Pt), and ruthenium (Ru).

Example 6: The method of any one of the preceding Examples, wherein the at least one dielectric material comprises at least one material selected from materials including silicon dioxide (SiO₂), silicon nitride (SiₓN_{y}), tantalum pentoxide (Ta₂O₅), aluminum oxide (Al₂O₃), hafnium oxide (HfO₂), zirconium dioxide (ZrO₂), lanthanum oxide (LaₓO_{y}), strontium titanate (SrTiO₃), and strontium oxide (SrO).

Example 7: The method of any one of the preceding Examples, wherein the silicon-carbide layer in the form of SiCₓO_{y} is a silicon-oxycarbide layer.

Example 8: In an exemplary embodiment, the disclosed subject matter describes a method for forming a silicon-carbide layer. The method includes forming a silicon nitride initiation-layer, in the form of SiₓN_{y}, substantially simultaneously over at least a dielectric material and a metal material. The silicon nitride initiation-layer is to serve as a growth-initiation layer. The silicon-carbide layer, in the form of SiCₓO_{y}; is formed over the silicon nitride initiation-layer. The formed silicon nitride initiation-layer is to substantially prevent a delay in a nucleation and growth of the silicon-carbide layer on the metal material in comparison with a nucleation and growth of the silicon-carbide layer on the dielectric material.

Example 9: The method of Example 8, further comprising forming the silicon nitride initiation-layer over a semiconductor material substantially simultaneously with the formation of the silicon nitride initiation-layer over at least the dielectric material and the metal material.

Example 10: The method of any one of the preceding Examples 8 et seq., wherein the silicon-carbide layer comprises at least one of doped silicon-carbide and undoped silicon-carbide.

Example 11: The method of any one of the preceding Examples 8 et seq., wherein a differential thickness between the formed silicon-carbide layer over the dielectric material and the metal material is less than about 2 nm.

Example 12: The method of any one of the preceding Examples 8 et seq., further comprising forming the silicon nitride initiation-layer substantially concurrently over combinations of different types of dielectric materials and different types of metal materials.

Example 13: The method of any one of the preceding Examples 8 et seq., wherein the silicon-carbide layer further comprises hydrogen.

Example 14: In an exemplary embodiment, the disclosed subject matter describes a method for forming a silicon-carbide layer. The method includes forming layers of at least one metal material and at least one dielectric material in a deposition chamber on a substrate, forming silicon nitride in the form of SiₓN_{y} as an initiation-layer over the at least one metal material and the at least one dielectric material on the substrate, and subsequently forming at least one layer over the silicon nitride where the at least one layer includes materials selected from materials including silicon carbide, in the form of SiₓC_{y}, silicon carbon nitride, in the form of SiₓC_{y}N_{z}, silicon oxycarbonitride, in the form of SiCₓN_{y}O_{z}, and silicon oxycarbide, in the form of SiₓC_{y}O_{z}.

Example 15: The method of Example 14, wherein the SiₓN_{y} is formed in the same chamber as the subsequent SiCₓO_{y} deposition in a direct-plasma operation.

Example 16: The method of any one of the preceding Examples 14 et seq., wherein the SiₓN_{y} is formed in a different chamber then the subsequent SiCₓO_{y} deposition in a remote-plasma operation.

Example 17: The method of any one of the preceding Examples 14 et seq., wherein the SiₓN_{y} is formed to have a thickness from about 20 nm to about 200 nm.

Example 18: The method of any one of the preceding Examples 14 et seq., wherein the SiₓN_{y} is formed to have a thickness less than about 20 nm.

Example 19: The method of any one of the preceding Examples 14 et seq., wherein the SiₓN_{y} is formed to have a thickness greater than about 200 nm.

Example 20: The method of any one of the preceding Examples 14 et seq., wherein the silicon carbide, the silicon carbon nitride, the silicon oxycarbonitride, and the silicon oxycarbide, can comprise at least one of doped and undoped versions of the listed silicon-based compounds.

What claimed is:

1. A method to produce a substantially uniform, silicon-carbide layer over both of at least one dielectric material and at least one metal material substantially concurrently, the method comprising:
forming a silicon-nitride layer, in the form of SiₓN_{y}, over the at least one dielectric material and the at least one metal material; and
forming the silicon-carbide layer, in the form of SiCₓO_{y}, over the silicon-nitride layer.

2. The method of claim 1, wherein the formed silicon-nitride layer is to substantially prevent a delay in a nucleation and growth of the silicon-carbide layer on the at least one metal material in comparison with a nucleation and growth of the silicon-carbide layer on the at least one dielectric material.

3. The method of claim 1, wherein the silicon-carbide layer further comprises hydrogen.

4. The method of claim 1, further comprising forming the silicon nitride layer over a semiconductor material.

5. The method of claim 1, wherein the at least one metal material comprises at least one material selected from materials including tungsten (W), titanium (Ti), tantalum (Ta), cobalt (Co), copper (Cu), platinum (Pt), and ruthenium (Ru).

6. The method of claim 1, wherein the at least one dielectric material comprises at least one material selected from materials including silicon dioxide (SiO₂), silicon nitride (SiₓN_{y}), tantalum pentoxide (Ta₂O₅), aluminum oxide (Al₂O₃), hafnium oxide (HfO₂), zirconium dioxide (ZrO₂), lanthanum oxide (LaₓO_{y}), strontium titanate (SrTiO₃), and strontium oxide (SrO).

7. The method of claim 1, wherein the silicon-car bide layer in the form of SiCₓO_{y} is a silicon-oxycarbide layer.

8. A method for forming a silicon-carbide layer, the method comprising:
forming a silicon nitride initiation-layer, in the form of SiₓN_{y}, substantially simultaneously over at least a dielectric material and a metal material, the silicon nitride initiation-layer to serve as a growth-initiation layer; and
forming the silicon-carbide layer, in the form of SiCₓO_{y}) over the silicon nitride initiation-layer, the formed silicon nitride initiation-layer to substantially prevent a delay in a nucleation and growth of the silicon-carbide layer on the metal material in comparison with a nucleation and growth of the silicon-carbide layer on the dielectric material.

9. The method of claim 8, further comprising forming the silicon nitride initiation-layer over a semiconductor material substantially simultaneously with the formation of the silicon nitride initiation-layer over at least the dielectric material and the metal material.

10. The method of claim 8, wherein the silicon-carbide layer comprises at least one of doped silicon-carbide and undoped silicon-carbide.

11. The method of claim 8, wherein a differential thickness between the formed silicon-carbide layer over the dielectric material and the metal material is less than about 2 nm.

12. The method of claim 8, further comprising forming the silicon nitride initiation-layer substantially concurrently over combinations of different types of dielectric materials and different types of metal materials.

13. The method of claim 8, wherein the silicon-carbide layer further comprises hydrogen.

14. A method for forming a silicon-carbide layer, the method comprising;
forming layers of at least one metal material and at least one dielectric material in a deposition chamber on a substrate;
forming silicon nitride in the form of SiₓN_{y} as an initiation-layer over the at least one metal material and the at least one dielectric material on the substrate; and
subsequently forming at least one layer over the silicon nitride, the at least one layer including materials selected from materials including silicon carbide, in the form of SiₓC_{y}, silicon carbon nitride, in the form of SiₓC_{y}N_{z}, silicon oxycarbonitride, in the form of SiCₓN_{y}O_{z}, and silicon oxycarbide, in the form of SiₓC_{y}O_{z}.

15. The method of claim 14, wherein the SiₓN_{y} is formed in the same chamber as the subsequent SiCₓO_{y} deposition in a direct-plasma operation.

16. The method of claim 14, wherein the SiₓN_{y} is formed in a different chamber then the subsequent SiCₓO_{y} deposition in a remote-plasma operation.

17. The method of claim 14, wherein the SiₓN_{y} is formed to have a thickness from about 20 nm to about 200 nm.

18. The method of claim 14, wherein the SiₓN_{y} is formed to have thickness less than about 20 nm.

19. The method of claim 14, wherein the SiₓN_{y} is formed to have a thickness greater than about 200 nm.

20. The method of claim 14, wherein the silicon carbide, the silicon carbon nitride, the silicon oxycarbonitride, and the silicon oxycarbide, can comprise at least one of doped and undoped versions of the listed silicon-based compounds.
